(19) United States
(12) Patent Application Publication
(10) Pub. No.: US 2026/0246283 A1
(43) Pub. Date: Aug. 20, 2026

(54) BIDIRECTIONAL ADAPTIVE TERMINAL VOLTAGE (BATV) WITH A BATTERY PACK

(71) Applicant: Proper Voltage, Inc., Carlsbad, CA (US)

(72) Inventors: Charles Welch, Carlsbad, CA (US); David Felzer, Carlsbad, CA (US)

(73) Assignee: Proper Voltage, Inc., Carlsbad, CA (US)

(21) Appl. No.: 19/644,792

(22) Filed: Apr. 10, 2026

Related U.S. Application Data
(63) Continuation of application No. 18/570,485, filed on Jun. 21, 2022.
(60) Provisional application No. 63/213,383, filed on Jun. 22, 2021.

(51) Int. Cl. H02J 7/04; B60L 53/20; B60L 53/22; H02J 7/00; H02J 7/50; H02J 7/80; H01M 10/42

(52) U.S. Cl. CPC H02J 7/04; B60L 53/20; B60L 53/22; H02J 7/50; H02J 7/80; H02J 7/855; H01M 10/425; H01M 2010/4271; H02J 2207/20

(57) ABSTRACT

A Bidirectional Adaptive Terminal Voltage (BATV) system has a battery system to be integrated into various devices (or external loads), without having to modify the electrical characteristics of the devices. The battery system includes a battery cell stack and a battery management system electrically coupled with one another. The battery management system is coupled with the BATV system, which is a bidirectional converter configured to operate in either a buck or boost mode, depending on the voltage conditions of an external load when power is required to be delivered from the battery system to the external load. When the battery system is being recharged from an external power supply or from regenerative energy absorption, the BATV system also operates in either buck or boost mode, as required by recharging conditions.

### CROSS-REFERENCES TO RELATED PATENT APPLICATIONS

This application claims benefit and priority under 35 U.S.C. § 120 as a continuation of U.S. Patent Application No. 18/570,485, filed December 14, 2023, which is a national stage entry pursuant to 35 U.S.C. § 371 of International Patent Application No. PCT/2022/073066, filed June 21, 2022, which claims benefit and priority under 35 U.S.C. § 119 to U.S. Provisional Patent Application No. 63/213,383, filed June 22, 2021, each of which is hereby incorporated by reference herein in its entirety.

### FIELD OF THE TECHNOLOGY

The present invention relates generally to battery systems. More particularly, the present invention relates to a Bidirectional Adaptive Terminal Voltage (BATV) system performing bidirectional DC to DC voltage and power regulation for use with managing the charge and discharge of a connected battery pack.

### BACKGROUND

Rechargeable batteries are widely used as energy storage devices in a variety of different applications; they have relatively high energy and power density and relatively low cost when compared to other energy storage technologies. Among available rechargeable battery types, the lithium-ion battery is highly favored and widely used due to its high power and energy density. The rechargeable batteries are integrated into portable electronics, consumer products, light electric vehicles, hybrid and electric vehicles, renewable power systems, and numerous other devices/systems.

However, integration of a rechargeable battery into different types of devices may be limited by the specifications of the power consuming portion of the device, including such common devices as motors, display screens, or other electronic devices requiring battery power. For instance, it is difficult to integrate a rechargeable battery into battery powered devices designed for an input voltage range different from the rechargeable battery’s true nominal voltage or voltage range. Additionally, for devices that also send power back to the battery system, the voltage delivered to the rechargeable battery pack must be kept within a certain range for the batteries to be safely charged, and therefore the system requires conditioning of the power and voltage delivered to the battery pack.

Accordingly, there remains a need for a system that allows seamless integration of a rechargeable battery into different devices for various applications without the requirement of ensuring that the device’s required voltages match up with the voltage range of the battery pack desired for use.

### BRIEF SUMMARY

To solve the foregoing problem, the present invention provides a Bidirectional Adaptive Terminal Voltage system (“BATV” herein). The BATV system enables integration of a rechargeable battery system into various devices (or connection to external loads) without having to modify the electrical characteristics of the devices into which they are integrated. The battery system includes a battery cell stack, which may contain one or more cells connected in series and/or parallel, and also includes a battery management system electrically coupled to the battery cell stack. The BATV combines electronic hardware and software that performs conversion, regulation, control, and communication functions.

In addition, the BATV system is a bidirectional converter, also variously referred to as a DC-DC, or buck/boost converter. The BATV system may regulate a current flowing between high voltage and low voltage ports in a direction designated by a direction control signal (DIR), and it may regulate a voltage across output terminals of the BATV system. Current levels and voltage regulation levels are programmed through a combination of analog and digital signals. Through the combination of analog and digital signals, the system is able to rapidly switch back and forth within milliseconds between power flowing from a low voltage port to a high voltage port and a high voltage port to a low voltage port, based on DIR inputs that dictate the device’s circumstantial needs.

Further, the BATV system may be electrically coupled to the battery system to form a battery pack. An external load may be connected to the battery pack via a positive terminal and a negative terminal of the battery pack going through the BATV system.

In an embodiment, when power is required to be delivered from the battery system to an external load, the BATV system operates in either a buck or boost mode, depending upon the voltage requirements of the external load and the current terminal voltage of the battery pack. Subsequently, when the battery system is being recharged from the external power supply or from regenerative energy absorption, the BATV system also operates in either a buck (step-down) or a boost (step-up) mode, as required by the recharging conditions. To that end, input and output voltage ranges and current flow may be programmable to enable the battery system to be used in applications requiring a variety of voltage and current specifications. Examples of various applications include different cell count battery stacks for the same or different output voltages, as well as different load or charge voltage and current characteristics for the same or different battery cell stacks.

An aspect of this disclosure is directed to a rechargeable battery pack. The rechargeable battery pack can include a battery cell stack coupled to a battery management system (BMS). The rechargeable battery pack can include a bidirectional adaptive terminal voltage system (BATV) coupled to said battery system. The BATV can combine electronic hardware and software. The BATV can be configured with a negative terminal and a positive terminal for coupling the rechargeable battery pack to a battery charger, to an external load, or to enable its integration into an electronic device without modifying the electrical characteristics of the devices into which it is integrated.

In some cases, the BMS can include one or more battery cell stack safety switches to facilitate connection and disconnection of the battery cell stack from the load or charger and to ensure safe use and to control current flow. The BMS can include an analog front end that monitors the voltage of the battery cell stack and current flowing into and out of the battery cell stack to control the safety and performance of the battery cell stack. The BMS can include a current sense resistor to sense the current flowing into and out of the battery system. The BMS can include a battery gauge to determine and report an accurate current state of charge, state of health of the battery system and for communications for internal and external signals.

In some cases, the BMS can further include a microcontroller for battery system management, which can include the management of communications between the BMS and the BATV required to synchronize the functionality and operation of the BMS and the BATV. The BMS can include a network of thermal management components to monitor the temperature of the battery cells and other components on the BMS printed circuit board assembly (PCBA). The BMS can include a communications component for communicating battery control and status to and from devices outside the battery pack. The BMS can include a display to show battery system status. The BMS can include a positive terminal and a negative terminal through which the BMS can be connected to other components or systems.

The rechargeable battery pack can include a data log to store data regarding the status and behavior of the battery system.

The rechargeable battery pack can include a GPS component to identify the time and the location of the battery pack.

In some cases, the thermal management components can include a network of digital temperature sensors configured to send signals to the microcontroller. The microcontroller can be programmed to reduce the maximum available charge or discharge power going through the battery system in the event that certain predetermined temperature thresholds are reached.

In some cases, the BATV can be a bidirectional buck-boost converter that performs conversion, voltage regulation, control, and communication functions. The BATV can be configured to regulate power flowing between high voltage and low voltage ports in a direction designated by a direction control signal and to regulate a voltage across output terminals of the BATV.

In some instances, the voltage being supplied externally to the high voltage port is fluctuating or is supplied at a fixed voltage, and the BATV is regulating to a specific fixed voltage to be delivered to the low voltage port.

In some instances, the voltage supplied externally to the high voltage port is fluctuating or is supplied at a fixed voltage, and the BATV is regulating to fixed current and fluctuating voltage to be delivered to the low voltage port.

In some instances, the voltage on the low voltage port is fluctuating and the BATV is regulating to a specific voltage to be delivered to the high voltage port for external use.

In some cases, the BATV can include FET safety switches configured to enable connection and disconnection of the rechargeable battery system from a load or a battery charger and for safe control of current flow. The BATV can include a current sense resistor that senses current flowing into and out of said battery pack. The BATV can include a buck-boost bidirectional FET assembly to switch current in the buck-boost function. The BATV can include a buck-boost bidirectional controller connected to the FET assembly to control the operation of the buck-boost conversion. The current sense resistor, the buck-boost bidirectional FET assembly, and the buck-boost bidirectional controller can be configured in combination in either a single phase or multiphase implementation.

The BATV system can include a microcontroller for BATV system management. The BATV can include at least one thermal sensor for monitoring the temperature of components in the BATV. The BATV can include a display to display BATV and/or battery system status.

In some cases, when power is required to be delivered from the battery pack system to an external load, the BATV system can operate in either a buck mode or a boost mode depending on the voltage requirements of the external load and the current terminal voltage of the battery pack.

When the rechargeable battery pack is being recharged from an external power supply or from regenerative energy absorption, the BATV system can operate in either a buck or boost mode as required by recharging conditions.

The BATV can be programmable to enable input and output voltage ranges and current flow suitable for a variety of voltage and current specifications.

An aspect of this disclosure is directed to a battery charging system. The battery charging system can include a rechargeable battery cell stack. The battery charging system can include a battery management system coupled to the battery cell stack. The battery charging system can include a bidirectional adaptive terminal voltage system coupled to the battery management system and configured for connection to a battery charger, to an external load, or for integration into an electronic device.

In some cases, the battery management system can be configured with hardware and software to monitor voltage of the battery cell stack and current flowing into and out of the battery cell stack. The hardware and software can be configured to sense the current flowing into and out of the battery system. The hardware and software can be configured to determine and report an accurate current state of charge or state of health of the battery system. The hardware and software can be configured to manage communications between the battery management system and the bidirectional adaptive terminal voltage system.

The bidirectional adaptive terminal voltage system can be a bidirectional buck-boost converter configured to regulate power flowing between high voltage and low voltage ports in a direction designated by a direction control signal, and to regulate a voltage across output terminals of said bidirectional adaptive terminal voltage system.

The bidirectional adaptive terminal voltage system can be programmable to enable input and output voltage ranges and current flow suitable for a variety of voltage and current specifications.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The embodiments disclosed herein will be further explained with reference to the attached drawings, which are not drawn to scale. Due emphasis is therefore placed on the principles of operation of the disclosed embodiments, of which:

FIG. 1 is a schematic diagram of a battery cell according to some embodiments;

FIG. 2 is a schematic diagram of a battery cell stack comprising multiple battery cells, according to some embodiments;

FIG. 3A is a block diagram of a battery management system, also according to some embodiments;

FIG. 3B is a schematic of battery cell stack safety switches incorporated in the battery management system of FIG. 3A;

FIG. 4 is a block diagram of a battery system.

FIG. 5 is a block diagram of the battery system of FIG. 4 connected with an external load;

FIG. 6 is a block diagram of a Bidirectional Adaptive Terminal Voltage (BATV) system according to some embodiments;

FIG. 7 is a block diagram of a battery pack; and

FIG. 8 is a block diagram of the battery pack connected with the external load.

### DETAILED DESCRIPTION

In the following description details are set forth to provide a thorough understanding of the present invention. It will be apparent to one skilled in the art that the present invention may be practiced without at least some of the specificity provided in these details. In other instances, apparatuses and methods are shown in a generalized form, i.e., a block diagram form, to facilitate the fundamental inventive concepts and principles of operation without needlessly complicating the present disclosure.

Reference in this specification to “one embodiment” or “an embodiment” means that a particular feature, structure, or characteristic described in connection with the embodiment is included in at least one embodiment of the present disclosure. The phrase “in one embodiment” in various places in the specification signifies that the feature or characteristic is not necessarily present in all embodiments, nor are separate or alternative embodiments mutually exclusive of other embodiments. Further, the terms “a” and “an” herein do not denote a limitation of quantity, but rather denote the presence of at least one of the referenced items or limitations. Moreover, various features are described that may be present in some embodiments while not in others. Similarly, various requirements are described that may be requirements for some embodiments but not for others.

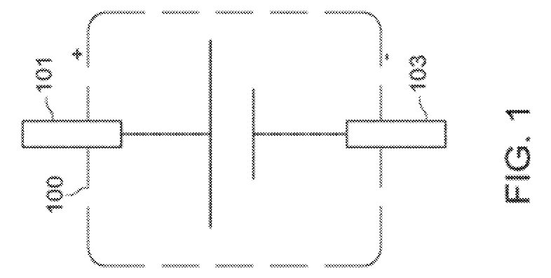

Referring first to FIG. 1, there is shown a schematic diagram of a battery cell 100 according to some embodiments. The battery cell 100 may be a rechargeable cell. For example, battery cell 100 may be a nickel-cadmium (NiCd) battery, a nickel-metal hydride (NiMH) battery, a lithium-ion (Li-ion) battery, a lithium-ion polymer (LiPo) battery, a lithium titanate (LTO) battery, or the like. The battery cell 100 includes two terminals, namely, a positive terminal 101 and a negative terminal 103. The battery cell 100 may be connected to other battery cells or any electronic device through the positive terminal 101 and the negative terminal 103. Specifications of the battery cell 100 are selected based on user requirements.

In an embodiment, the battery cell 100 of following specifications may be used: 1.5 V~2.7 V, 2.3 V nominal, 23 Ah, 52 Wh, 106×116×22 mm, (6.17×6.57×0.87 in), 550 g (19.6 oz, 1.21 lbs), 96 Wh/kg, 202 Wh/L, –30~55° C. operating, 115 A charge/discharge (continuous), 200 A Max (<10 seconds).

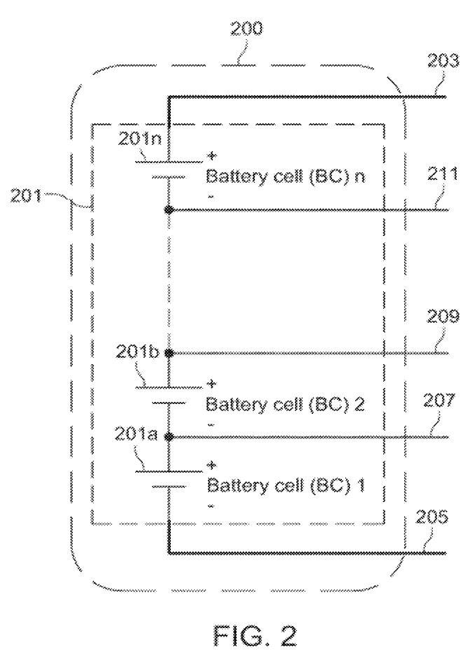

According to an embodiment, multiple battery cells are used to form a battery cell stack. For instance, the multiple battery cells may be connected end-to-end to form the battery cell stack as described below and with reference to FIG. 2.

FIG. 2 is a schematic diagram of a battery cell stack 200 made up of multiple battery cells 201 а-201 n, according to some embodiments. The multiple battery cells 201а-201n are connected end-to-end in series, i.e., a positive terminal of the battery cell 201 a is connected to a negative terminal of the battery cell 201b, and then again a positive terminal of the battery cell 201b is connected to a negative terminal of another battery cell, and so on, to form the battery cell stack 200. In some alternate embodiments, the multiple battery cells 201 а-201 n may be connected in parallel. The battery cell stack 200 includes two terminals, namely, a positive terminal 203 and a negative terminal 205. The battery cell stack 200 may be connected to any external electronic device through the positive terminal 203 and the negative terminal 205. Additionally, in some embodiments, a terminal is associated with each battery cell of the multiple battery cells 201 а-201n. For example, terminals 207, 209, and 211 are associated with the battery cells 201а, 201b, and 201n, respectively.

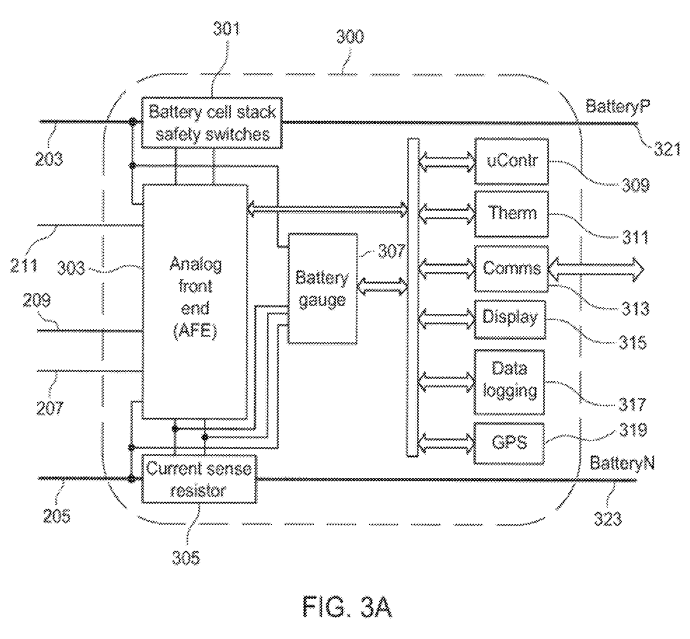

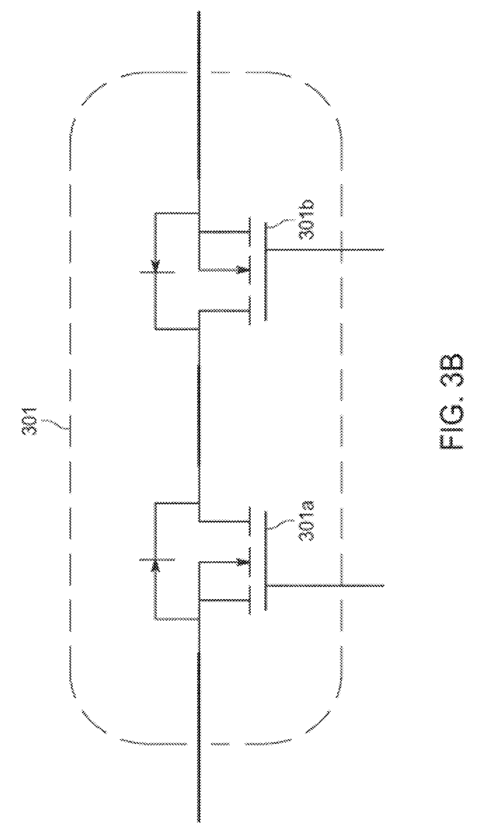

Further, the battery cell stack 200 may be connected to a battery management system, as described below and with reference first to FIG. 3A.

FIG. 3A is a block diagram of a battery management system 300, according to some embodiments of the present invention. The battery management system (or BMS) 300 is coupled to the battery cell stack and is used for control, safety, and information monitoring of the battery cell stack 200. Combined, the battery cell stack and the battery management system are referred to herein as a battery system. The battery management system 300 includes battery cell stack safety switches 301, which facilitate connection and disconnection of the battery cell stack from the load or charger to ensure safe use and to control current flow, an analog front end (AFE) 303, which monitors the voltage of the battery cell stack and current flowing into and out of the battery cell stack to control the safety and performance of the battery cell stack, a current sense resistor 305 to sense the current flowing into and out of the battery cell stack, and a battery gauge 307 to determine and report the state of health of the battery cell stack, communications for internal and external signals, and so forth.

Additionally, the battery management system (BMS) 300 includes a microcontroller 309 for battery system management, a thermal management component 311 for monitoring the temperature of the battery cells and other components in the BMS, a communications component 313 for communicating battery control and status to and from devices outside the battery system, a display component 315 to display battery system status, a data logging component 317 to store data regarding the status and behavior of the battery system, and a GPS component 319 to identify the time and the location of the battery system. The thermal management component 311 is a discrete digital temperature sensor for thermal monitoring and sends signals to the microcontroller. It enables the ability to reduce the maximum available charge or discharge power going through the system in the event that certain predetermined temperature thresholds are reached, and thereby to protect the onboard electronics from overheating. The system preferably includes at least one pulse width modulation (PWM) controlled fan for cooling high heat generating components on the PCBA, such as the FETs and inductors or other magnetics in the system that require specific operating temperature ranges to maintain peak power output. Fan operation and speed is dictated by the microcontroller, which is programmed to base fan speed decisions on predetermined temperature thresholds and readings from the thermal sensor(s). The microcontroller is programmed such that prior to limiting available power in and out of the battery pack, the microcontroller communicates to the PWM cooling fan to increase its speed to increase airflow circulation over the components generating heat in the system and thereby to allow the system to continue to operate at its full potential.

The battery management system 300 further includes a positive terminal 321 and a negative terminal 323 through which the battery management system 300 can be connected to other components or systems, including external components and systems.

FIG. 3B is a schematic diagram of battery cell stack safety switches 301 incorporated in the battery management system of FIG. 3A. Battery cell stack safety switches 301 comprise a first switch 301а and a second switch 301b. The combination of the first and second switches allows passing current into or blocking of current from the battery cell stack. This represents one possible implementation of the switch function. The switch function may also be implemented in other circuit device structures and combinations and in such implementations may require different numbers of components.

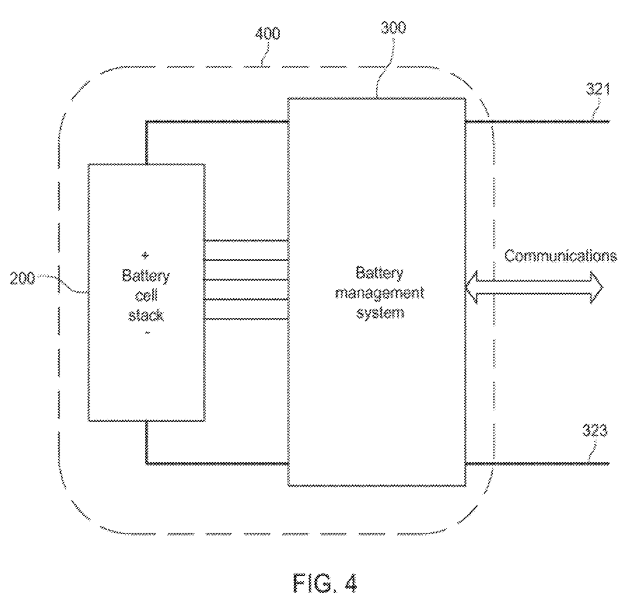

FIG. 4 is a block diagram of a battery system 400 according to various embodiments. The battery cell stack 200 and the battery management system 300 electrically coupled to one another are collectively characterized as the battery system 400. The positive terminal 321 and the negative terminal 323, respectively, may act as a positive terminal and a negative terminal of the battery system 400. The battery system 400 may be connected to an external load and may supply electrical energy to the external load. The battery system 400 may also be connected to an external charger and may thus be charged by the external charger.

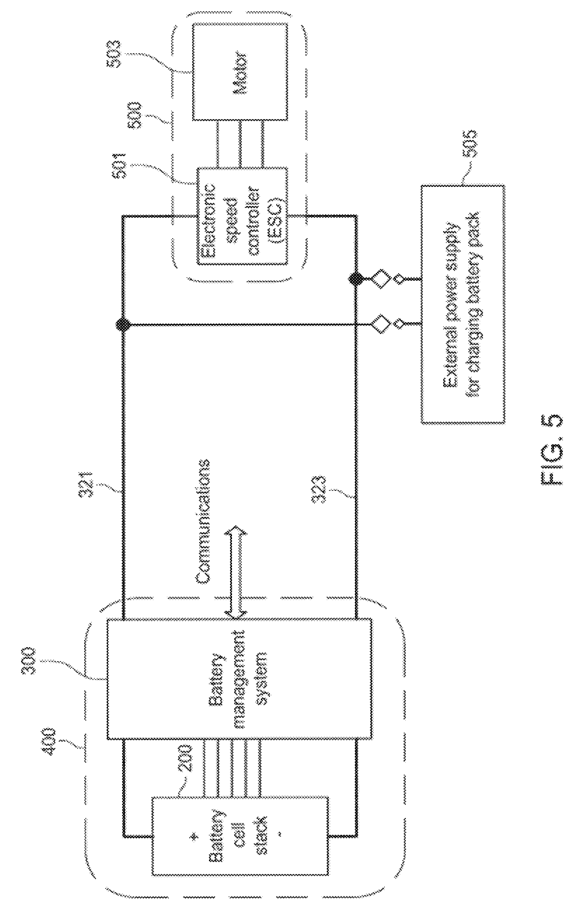

FIG. 5 is a block diagram of the battery system 400 connected to an external load 500, according to some embodiments. In an embodiment, the external load 500 may include an electronic speed controller 501 and a variable speed motor 503. The electronic speed controller 501 is configured to control a speed of the motor 503. The battery system 400 may discharge the electrical energy across the external load 500 to operate the external load 500. In some embodiments, the battery system 400 may be charged using an external power supply 505, which in embodiments may be a direct current (DC) source.

Different types of external loads within which the battery system 400 may be integrated are limited by the specification of the battery cell stack 200. For instance, it is difficult to integrate the battery system 400 with battery powered devices designed for an input voltage range which is different than the battery cell stack’s 200 true nominal voltage or voltage range.

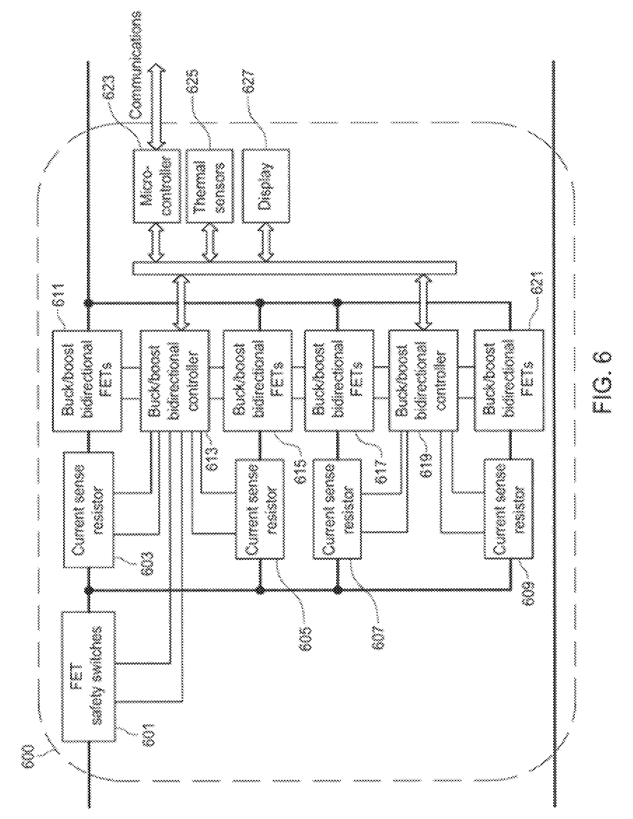

To address this limitation a Bidirectional Adaptive Terminal Voltage (BATV) system is provided. FIG. 6 is a block diagram of such a BATV system 600. The BATV system 600 allows the battery system 400 to be integrated into various devices (or external loads), without modifying the electrical characteristics of the devices into which they are integrated. The BATV system 600 is a combination of electronic hardware and software that performs conversion, configuration, control, and communication functions. In addition, the BATV system 600 is a bidirectional converter, sometimes referred to as either a DC-DC or a buck/boost converter. The BATV system 600 may regulate a current flowing between high voltage and low voltage ports in a direction designated by a direction control signal (DIR) and may regulate a voltage across output terminals of the BATV system 600. Current and voltage regulation levels are programmed through analog or digital signals flowing in the BATV system 600. The BATV system 600 comprises FET safety switches 601 that enable connection and disconnection of the battery from the load or charger for safety or for control of current flow. A current sense resistor 603 senses the current flowing into and out of the battery pack, and a buck/boost bidirectional FET assembly 611 (to switch current in the buck-boost function) is connected to a buck-boost bidirectional controller 613 to control the operation of the buck-boost conversion. The combination of the current sense resistor 603, buck-boost bidirectional FET assembly 611, and buck-boost bidirectional controller 613 may be constructed in either a single phase or multiphase implementation. The BATV system 600 further comprises a microcontroller 623 for BATV system management, thermal sensor(s) 625 for monitoring the temperature of components in the BATV, and a display 627 to display BATV and battery system status. Note that in this view, there are four sets of buck-boost FETs shown with two buck-boost controller blocks. In other embodiments, a controller may be provided for every FET pair.

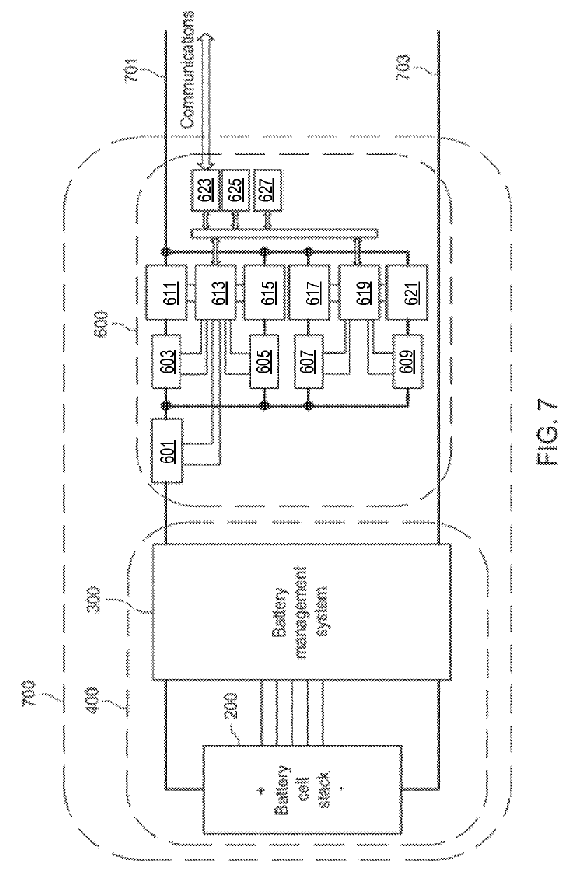

The BATV system 600 may be electrically coupled to the battery system 400 to form a battery pack, as described now with reference to FIG. 7, which is a block diagram of a battery pack 700, according to some embodiments. A combination of the battery system 400 and the BATV system 600 electrically coupled with one another is referred to as the battery pack 700. The battery pack 700 may be connected to the external load 500 via a positive terminal 701 and a negative terminal 703. Input and output voltage ranges and the current flow may be programmable to enable the battery system 400 to be used in applications where a variety of voltage and current specifications are required. Some examples of various applications are different cell battery stacks for the same or different output voltages, and different load or charge current characteristics for the same or different battery cell stacks.

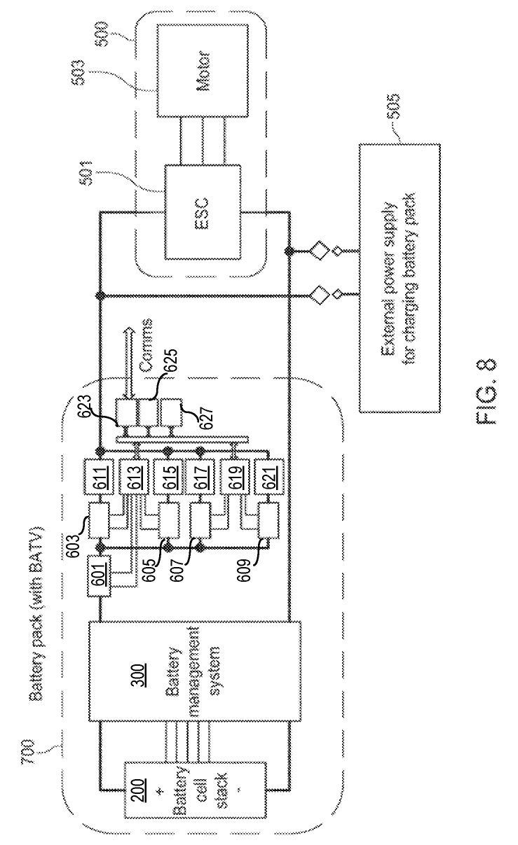

FIG. 8 is a block diagram of an exemplary application of the battery pack 700, according to some embodiments. The battery pack 700 is connected to an external load 500. When power is delivered from the battery system 400 to the external load 500, the BATV system 600 operates in either a buck or boost mode, depending upon the voltage conditions of the external load 500. Subsequently, when the battery system 400 is being recharged from the external power supply 505 or from regenerative energy absorption, the BATV system 600 also operates in either buck or boost mode, as required by recharging conditions. To that end, the BATV system 600 enables the battery system 400 to be used for different applications involving different load voltages and currents. Further, the BATV system 600 allows the battery system 400 to be recharged from different external power supplies.

The foregoing description provides exemplary embodiments only, and is not intended to limit the scope, applicability, or configuration of the disclosure. Rather, the disclosure herein of the exemplary embodiments will provide those skilled in the art with an enabling description for implementing one or more exemplary embodiments. Contemplated as encompassed within the scope of the claims are various changes that may be made in the function and arrangement of elements without departing from the spirit and scope of the subject matter disclosed, which is set forth in the appended claims.

What is claimed is:

1. A rechargeable battery pack that integrates with an external device, comprising:
a battery system, comprising:
a battery cell stack;
a battery management system (BMS) electrically coupled with the battery cell stack; and
a first controller;
a cooling device;
a bidirectional adaptive terminal voltage (BATV) system electrically interposed between the battery system and the external device, the BATV system comprising:
at least one thermal sensor configured to measure a temperature of at least one portion of the rechargeable battery pack;
external terminals electrically coupled with the external device;
BMS terminals electrically coupled with the BMS, wherein the BMS is electrically coupled with the battery cell stack;
a bidirectional buck-boost converter configured to step up voltage from a low voltage port corresponding to the BMS terminals to a high voltage port corresponding to the external terminals; and
a second controller,
wherein:
the first controller of the battery system is configured to:
receive temperature data from the at least one thermal sensor;
determine, based on the received temperature data, that a temperature of the rechargeable battery pack exceeds a first threshold; and
send, responsive to the determination that the temperature of the rechargeable battery pack exceeds the first threshold, a first control signal to the cooling device to cause the cooling device to increase a cooling rate of the rechargeable battery pack; and
the second controller of the BATV is configured to:
regulate, according to a second control signal indicating a direction of power flow, a power flow between the low voltage port corresponding to the BMS terminals and the high voltage port corresponding to the external terminals, wherein a first voltage at the high voltage port is greater than a second voltage at the low voltage port;
regulate, without modification to electrical characteristics of the external device, and based on adjusting the power flow, at least one of (i) a programmable voltage across the external terminals coupled with the external device or (ii) a programmable current level flowing through the external terminals; and
reduce, responsive to an indication that the temperature exceeds a second threshold higher than the first threshold, the power flow between the low voltage port and the high voltage port.

2. The rechargeable battery pack of claim 1, wherein the first controller is further configured to:
increase the cooling rate prior to the second controller reducing the power flow.

3. The rechargeable battery pack of claim 1, wherein the cooling device comprises a variable‑speed fan, and to increase the cooling rate, the first controller is further configured to:
cause an increase in a duty cycle of a fan control signal provided to the cooling device.

4. The rechargeable battery pack of claim 1, wherein to reduce the power flow, the second controller is further configured to:
limit at least one of a maximum output current of the bidirectional buck-boost converter or a maximum power transfer rate through the bidirectional buck-boost converter.

5. The rechargeable battery pack of claim 1, wherein the first controller is further configured to:
access, from memory, a first temperature value corresponding to the first threshold; and
access, from the memory, a second temperature value corresponding to the second threshold, wherein the first temperature value is different from the second temperature value.

6. The rechargeable battery pack of claim 1, comprising:
the at least one thermal sensor mounted on a circuit board associated with the BATV system.

7. The rechargeable battery pack of claim 1, wherein:
the low voltage port corresponds to a battery-system side of the bidirectional buck-boost converter, and
the high voltage port corresponds to an external-terminal side of the bidirectional buck-boost converter.

8. The rechargeable battery pack of claim 1, wherein the bidirectional buck-boost converter is further configured to:
operate in a buck mode when the second voltage exceeds the first voltage.

9. The rechargeable battery pack of claim 1, wherein the second controller is further configured to:
regulate the programmable voltage or the programmable current independently of a state of charge of the battery cell stack.

10. The rechargeable battery pack of claim 1, wherein the external terminals are configured to supply power to a plurality of different types of external devices having different operating voltage requirements.

11. The rechargeable battery pack of claim 1, wherein the BATV system is further configured to:
regulate the programmable voltage across the external terminals while the battery cell stack voltage varies during discharge.

12. The rechargeable battery pack of claim 1, wherein the first controller and the second controller are implemented on separate processing devices.

13. The rechargeable battery pack of claim 1, wherein the second controller is further configured to:
reduce the power flow without disabling power delivery to the external device.

14. A method, comprising:
providing a rechargeable battery pack that integrates with an external device, comprising:
a battery system, comprising:
a battery cell stack;
a battery management system (BMS) electrically coupled with the battery cell stack; and
a first controller;
a cooling device;
a bidirectional adaptive terminal voltage (BATV) system electrically interposed between the battery system and the external device, the BATV system comprising:
at least one thermal sensor configured to measure a temperature of at least one portion of the rechargeable battery pack;
external terminals electrically coupled with the external device;
BMS terminals electrically coupled with the BMS, wherein the BMS is electrically coupled with the battery cell stack;
a bidirectional buck-boost converter configured to step up voltage from a low voltage port corresponding to the BMS terminals to a high voltage port corresponding to the external terminals; and
a second controller,
receiving, by the first controller of the battery system, temperature data from the at least one thermal sensor;
determining, by the first controller, based on the received temperature data, that a temperature of the rechargeable battery pack exceeds a first threshold;
sending, by the first controller, responsive to the determination that the temperature of the rechargeable battery pack exceeds the first threshold, a first control signal to the cooling device to cause the cooling device to increase a cooling rate of the rechargeable battery pack; and
regulating, by the second controller of the BATV, according to a second control signal indicating a direction of power flow, a power flow between the low voltage port corresponding to the BMS terminals and the high voltage port corresponding to the external terminals, wherein a first voltage at the high voltage port is greater than a second voltage at the low voltage port;
regulating, by the second controller, without modification to electrical characteristics of the external device, and based on adjusting the power flow, at least one of (i) a programmable voltage across the external terminals coupled with the external device or (ii) a programmable current level flowing through the external terminals; and
reducing, by the second controller, responsive to an indication that the temperature exceeds a second threshold higher than the first threshold, the power flow between the low voltage port and the high voltage port.

15. The method of claim 14, comprising:
increasing, by the first controller, the cooling rate prior to the second controller reducing the power flow.

16. The method of claim 14, wherein the cooling device comprises a variable‑speed fan, and to increase the cooling rate, the method further comprises:
causing, by the first controller, an increase in a duty cycle of a fan control signal provided to the cooling device.

17. The method of claim 14, comprising:
accessing, by the first controller, from memory, a first temperature value corresponding to the first threshold; and
accessing, by the first controller, from the memory, a second temperature value corresponding to the second threshold, wherein the first temperature value is different from the second temperature value.

18. The method of claim 14, comprising:
operating, by the bidirectional buck-boost converter, in a buck mode when the second voltage exceeds the first voltage.

19. The method of claim 14, comprising:
regulating, by the second controller, the programmable voltage or the programmable current independently of a state of charge of the battery cell stack.

20. The method of claim 14, comprising:
regulating, by the BATV system, the programmable voltage across the external terminals while the battery cell stack voltage varies during discharge.
